(19) United States
(12) Patent Application Publication
(10) Pub. No.: US 2012/0081860 A1
(43) Pub. Date: Apr. 5, 2012

(54) PRE-TREATMENT OF MEMORY CARDS FOR INK JET PRINTING

(76) Inventors: Itzhak Pomerantz, Kefar Sava (IL); Shiv Kumar, Saharanpur (IN); Robert Miller, San Jose, CA (US); Chin-Tien Chiu, Taichung City (TW); Peng Fu, Kunshan (CN); Cheeman Yu, Fremont, CA (US); Hem Takiar, Fremont, CA (US); Chih Chiang Tung, Taichung County (TW); Kaiyou Qian, Shanghai (CN)

(21) Appl. No.: 13/129,510

(22) PCT Filed: Oct. 4, 2010
(86) PCT No.: PCT/CN2010/077567

§ 371 Date: Oct. 20, 2011

(51) Int. Cl. H05K 1/14; B32B 3/10; B32B 3/02; H05K 7/00; B32B 3/30

(52) U.S. Cl. 361/737; 361/728; 428/156; 428/76; 428/195.1; 428/167

(57) ABSTRACT

A memory device is disclosed including at least one surface pre-treated to roughen the surface for better adhesion of ink on the surface. The surface of the memory device may be pre-treated by scoring lines in the surface with a laser or by forming discrete deformations with a particle blaster. The surface may also be roughened by providing a roughened pattern on a mold plate during an encapsulation process. In further examples, the surface may be chemically pre-treated to roughen the surface and/or increase the adhesion energy of the surface.

### BACKGROUND OF THE INVENTION

1. Field

The present technology relates to fabrication of semiconductor devices.

2. Description of Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

Many memory devices, such as memory cards, have indicia on them to indicate the manufacturer of the memory device and its internal characteristics, such as its storage capacity. For some memory devices, such as some SD cards, the indicia is printed on a label, which is applied to the card during the manufacturing process. However, for other memory devices, such as some microSD cards, the presence of a label can result in an unacceptable overall card thickness. For such cards, the indicia is printed directly onto the device during the manufacturing process.

As one example of a process for fabricating cards with printed indicia, the cards are assembled with memory die and controller die mounted to a substrate, and then encapsulated in molding compound. Typically, the cards are batch processed a number at a time on a panel or strip for economies of scale. After encapsulation, the indicia can be printed onto the cards as a group using a pad printing process. In this process, the indicia for each of the cards is placed on a printing plate. The indicia is then transferred from the printing plate onto a silicone pad, and the silicone pad is pressed against the strip of memory cards. The memory cards are later separated from the strip.

In addition to or instead of current markings on a memory card, next generation memory cards are going to include a much greater wealth of information, in richer and more colorful text and images. While pad printing adds less thickness to a memory card as compared to a label, the adhesion between the molding compound and print ink is poor. Thus, the ink may bleed, and may also be rubbed off or smudged in processes following the print process.

While texturing of surfaces to receive an ink may be known, printing on memory cards presents some unique challenges. For one thing, the thickness of a memory card is defined by applicable standards, and nearly every micron in the thickness dimension is accounted for the memory die, electrical connections and molding compound. There simply is not enough room to print normal thickness ink layers on the card. Reducing the thickness of the ink also reduces the mechanical strength of the ink layer and the adhesion force of the ink on the card.

A second challenge to printing on memory cards is that there is typically a lubricant such as a wax or oil added to the molding material during the encapsulation process of the memory cards to facilitate removal of the encapsulated cards from the mold. This lubricant interferes with the ability of the ink to bond with the surface. Even where the lubricant is removed from a surface of the cards, it can happen thereafter that the lubricant beneath the surface migrates to the surface. If the ink has not properly bonded with the surface, this migration can result in poor adhesion of the ink on the surface.

### DESCRIPTION OF THE DRAWINGS

FIG. 1 is a front view of a memory device to which embodiments of the present technology may be applied.

FIG. 2 is a rear view of a memory device to which embodiments of the present technology may be applied.

FIG. 3 is a panel of memory devices, prior to encapsulation, to which embodiments of the present technology may be applied.

FIG. 4 is a panel of memory devices, after encapsulation, to which embodiments of the present technology may be applied.

FIG. 5 is a representation of a first embodiment of the present technology for texturing a memory device using a laser.

FIG. 6 is a cross-sectional view transverse to the direction of the pre-treated laser lines of FIG. 5.

FIG. 7 is a magnified top view photograph of the pre-treated rows formed by the embodiment of FIG. 5.

FIG. 8 is a cross-sectional view through the pre-treated rows shown for example in the photograph of FIG. 7.

FIG. 9 is a representation of a second embodiment of the present technology for texturing a memory device using a laser.

FIG. 10 is a cross-sectional view showing texture in the encapsulated surface of FIG. 9.

FIG. 11 shows a different cross-sectional view of the texture in the encapsulated surface of FIG. 9.

FIG. 12 shows an edge view of a panel of substrate and die assemblies surrounded by a pair of mold plates for encapsulating the panel according to a third embodiment of the present technology.

FIG. 13 shows an edge view of a panel of leadframe and die assemblies encased by a pair of mold plates during an encapsulation process.

FIG. 14 shows a view of an encapsulated and pre-treated panel according to the embodiment of FIGS. 12 and 13.

FIGS. 15 and 16 illustrate the contact angles of drops of ink on a surface of a memory device before and after pre-treatment in accordance with the present technology.

FIG. 17 is a schematic representation of a plasma chamber for pre-treating memory devices according to a fourth embodiment of the present technology.

FIG. 18 is a schematic representation of an interfacial agent chamber for pre-treating memory devices according to a fifth embodiment of the present technology.

FIG. 19 is a molecular level illustration of bonds in the molding compound of a memory device which are weakened or broken by the interfacial agent.

FIG. 20 is an enlarged view of a roughened surface according to any of the embodiments of the present technology.

FIG. 21 is an enlarged view of the roughened surface of FIG. 17 having a layer of ink thereon.

FIG. 22 is pre-treated memory device including a primer layer.

FIG. 23 is a pre-treated memory device including graphical content.

### DETAILED DESCRIPTION

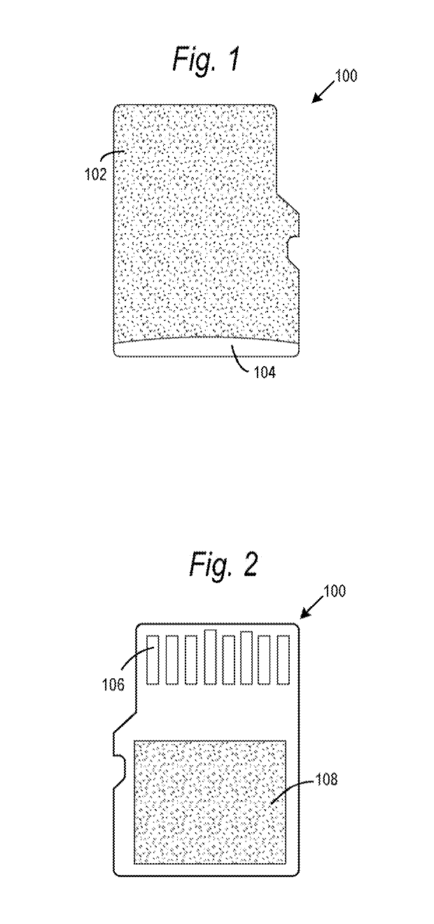

Embodiments will now be described with reference to FIGS. 1 through 23, which relate to a memory device having at least one pre-treated surface for better adhesion of ink on the surface. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top,” “bottom,” “upper,” “lower,” “vertical” and/or “horizontal” as may be used herein are for convenience and illustrative purposes only, and are not meant to limit the description of the invention inasmuch as the referenced item can be exchanged in position.

FIG. 1 shows a front view of a memory device 100 having a pre-treated surface 102 for receiving ink in accordance with the present technology. The pre-treated surface 102 in FIG. 1 takes up substantially the entire front surface of the memory device 100, with the exception of a finger grip 104 formed on the front surface of memory device 100. However, in further embodiments, a smaller portion of the front surface may be pre-treated, or the entire front surface, including finger grip 104, may be pre-treated.

FIG. 2 shows a rear view of a memory device 100 having contact fingers 106 for establishing an electrical connection with a host device in which the device 100 is seated. FIG. 2 also shows a pre-treated portion 108 which is pre-treated to receive ink in accordance with the present technology. Portion 108 is shown taking up only part of the back surface of memory device 100. In further embodiments, the pre-treated portion 108 on the rear surface of memory device 100 may take up the entire rear surface of the memory device 100 with the exception of contact fingers 106. Moreover, as explained below, memory device 100 may have electrical contacts other than contact fingers 106 on a rear surface of the memory device. In such embodiments, the pre-treated portion 108 on the rear surface may take up a portion of the rear surface, or all of the rear surface except for the electrical contacts.

FIGS. 1 and 2 show an example where memory device 100 is a MicroSD card. However, it is understood that memory device 100 may be any device that comprises a non-volatile memory operative to store information. Examples of memory devices include, but are not limited to, handheld, removable memory cards (such as SD or microSD cards), handheld universal serial bus (“USB”) flash drives (“UFD”), embedded memory devices and removable or non-removable hard drives (such as solid-state drives).

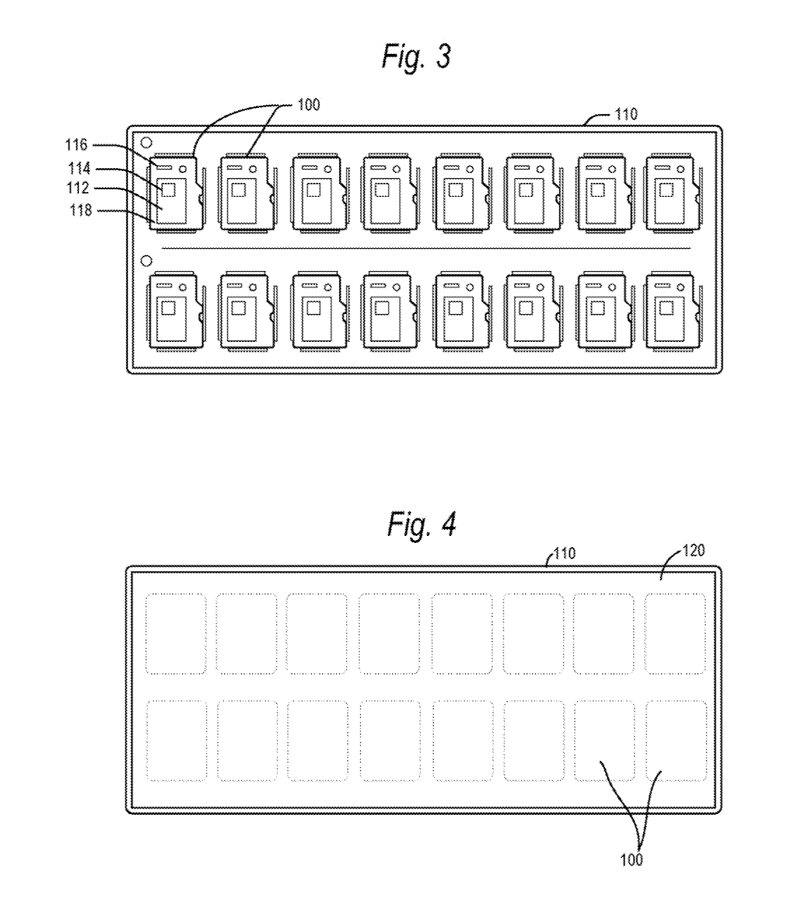

FIG. 3 shows a panel 110 for batch processing a number of memory devices 100 at the same time. FIG. 3 shows the memory devices 100 prior to encapsulation. Each memory device may be formed with one or more memory die 112, a controller die 114 and passive components 116 (numbered on one memory device 100 in FIG. 3) physically and electrically coupled to a substrate 118. As shown in FIG. 4, after the memory die 112 and controller die 114 are mounted and electrically coupled to the substrate, the internal components (at least the die 112, 114 and passive components 116) on panel 110 may be encapsulated in a molding compound 120.

The molding compound 120 may be an epoxy resin such as for example available from Sumito Corp. or Nitto Denko Corp., both having headquarters in Japan. Other molding compounds from other manufacturers are contemplated. The molding compound 120 may be applied according to various processes, including by transfer molding or injection molding techniques. The molding compound 120 covers at least the memory die 112, the controller die 114 and the passive components 116. The contact fingers 106 may be left uncovered and exposed so that they may be mated with terminals in a host device.

In FIGS. 1 and 2, the pre-treated surfaces 102 and 108 are formed in the molding compound of the memory device 100. In further embodiments, the one or more memory die 112 and/or controller die 114 may themselves be encapsulated in a molding compound prior to being connected to the substrate 118. In such embodiments, the encapsulated memory die and/or controller die may themselves be considered “memory devices” as that term is used herein.

The underlying memory die in the memory device 100 can take any suitable form; preferably solid-state memory (e.g., flash), although other types of memory can be used. While a memory device 100 is used to illustrate the pre-treatment techniques of these embodiments, these pre-treatment techniques can be adapted for use with other items, such as items used in conjunction with memory devices (e.g., memory device readers and memory device lids).

The embodiments of FIGS. 1 and 2 may show the front and rear surfaces of the same memory device 100 (with both the front and rear sides having pre-treated surfaces). In further embodiments, one or the other of the front and rear surfaces may be pre-treated as explained below, and the other surface have no pre-treatment. Moreover, while the memory device 100 may have a small thickness, it is contemplated that some or all of the edges between the front and back surfaces of memory device 100 may be pre-treated in accordance with the present technology so as to receive an ink.

As discussed above, it is often desired for a memory device to include visible indicia that provides information such as, for example, the manufacturer of the memory device and the memory device's internal characteristics, such as its storage capacity. In contrast to the prior methods discussed above that apply a sticker to the memory device or that use a pad printing process to print relatively simple indicia, the method and system disclosed herein provide a mechanism to print more complex and/or colorful indicia, referred to herein as “graphical content,” onto one or more surfaces of memory devices in a batch. In particular, the present technology relates to pre-treating one or more surfaces on memory devices 100 in a batch in preparation for receiving graphical content.

“Graphical content” as used herein may refer to any indicia that can be printed onto a memory device. Examples of graphical content include, but are not limited to, pictures, photographs, decorative designs, logos, colors, symbols, text, and any combination thereof. It should be noted that graphical content can include text only and does not necessarily need to include a picture. Graphical content can convey information about an internal characteristic or property of the memory device, such as its storage capacity (e.g., 1 GB, 16 GB, etc.). The graphical content may reveal information relating to the type of content stored on the memory device, such as for example a picture of a musical note, to indicate the memory device is storing music, or a picture of a camera to indicate the memory device is storing pictures. The graphical content may alternatively be decorative, having no relation to the type of device or content, but provided so as to appeal to a certain segment of the market. The graphical content may be other indicia in further examples. Additional examples of the types of graphical content which may be provided on a surface of a memory device are set forth in U.S. Provisional Patent Application No. 61/253,271, entitled “Method and System for Printing Graphical Content onto a plurality of Memory Devices and for Providing a Visually Distinguishable Memory Device, filed Oct. 20, 2009, which provisional patent application is incorporated herein by reference in its entirety.

The following describes various embodiments for pre-treating one or more surfaces of a memory device 100 to facilitate application of a graphical content to the one or more surfaces. As used herein, “pre-treating” may refer to roughening and/or texturing one or more surfaces of a memory device, chemically treating one or more surfaces of a memory device, or otherwise processing one or more surfaces of the memory device to increase the capability of the surface(s) to receive and hold an ink.

In embodiments, pre-treatment of memory device surface(s) according to the various embodiments may be performed on surfaces of the molding compound 120 after a panel of memory devices has been encapsulated and before the panel has been singulated. However, it is contemplated that pre-treatment may alternatively be performed after singulation. For example, pre-treatment may be performed in the molding compound 120 of individual memory devices 100. In further embodiments, pre-treatment may be performed on lids in which encapsulated memory devices are housed. In at least one embodiment described below, the pre-treatment in accordance with the present technology occurs during the encapsulation process. In the embodiments described below, the pre-treatment process is performed on memory devices 100 while the devices are still part of panel 110. However, as noted, pre-treatment may be performed on individual memory devices after they are singulated from panel 110.

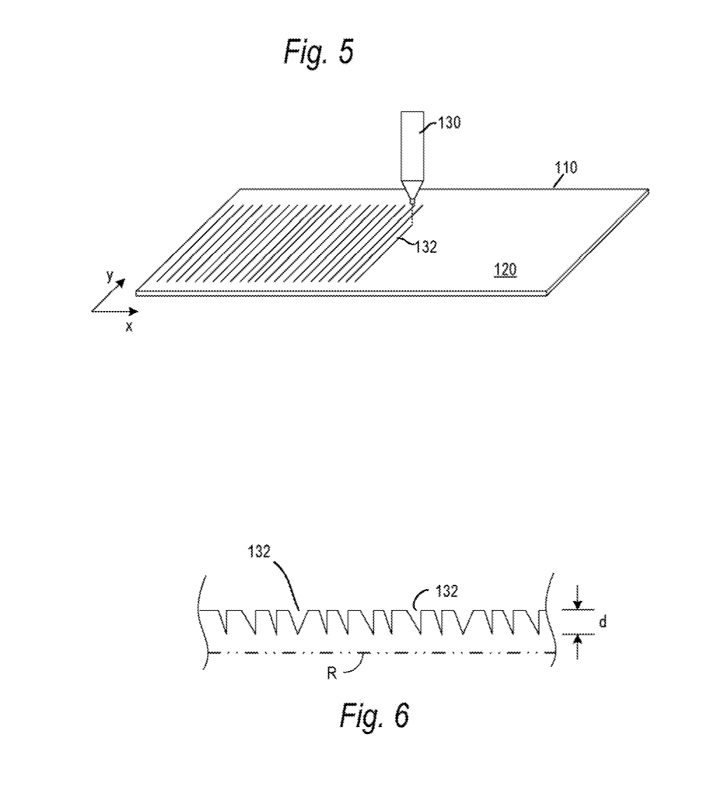

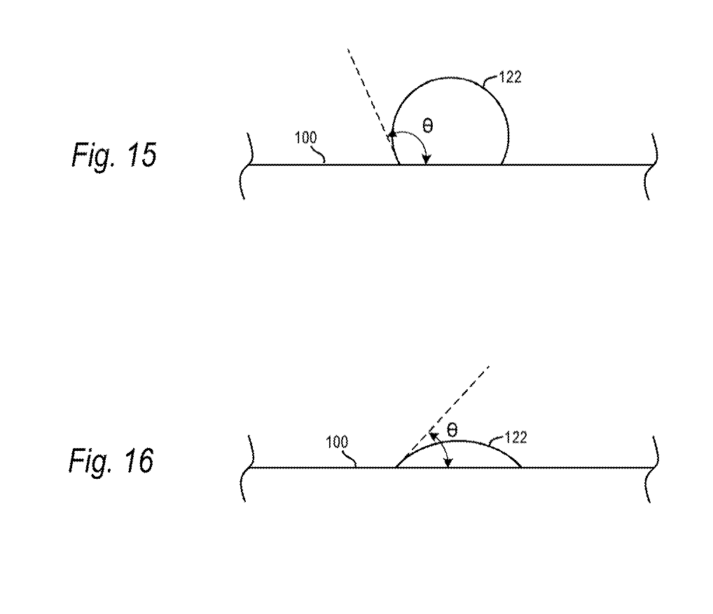

The present technology improves the ability to receive and hold an ink by at least two distinct pre-treatment operations. A first of these operations relates to a mechanical pre-treating of the surface of the molding compound and the second of these operations relates to chemical pre-treating of the surface of the molding compound. Mechanical pre-treating will next be described with reference to FIGS. 5-14 and chemical pre-treating is described thereafter with reference to FIGS. 15-19.

Mechanical pre-treating of a surface 102 and/or 108 of the molding compound 120 is performed by providing a roughened texture to the surface by scoring, abrading or other mechanical process. A first embodiment of mechanical pre-treating is described with reference to FIGS. 5-8. In this embodiment, one or more surfaces of memory device 100 are scored by laser ablation to provide a roughened texture to the scored surface. FIG. 5 shows a laser 130 scoring the molding compound 120 on a panel 110. In one embodiment, the laser may form a plurality of texture lines 132 in the molding compound 120, which lines may be oriented parallel to the shown x-axis, y-axis or at some oblique angle to the x- and y-axes. The laser 130 may be a known laser, for example producing coherent light in the red, green or other wavelength. The laser 130 may for example output a beam having 7 to 8 watts of energy as it moves across the surface of the panel 110.

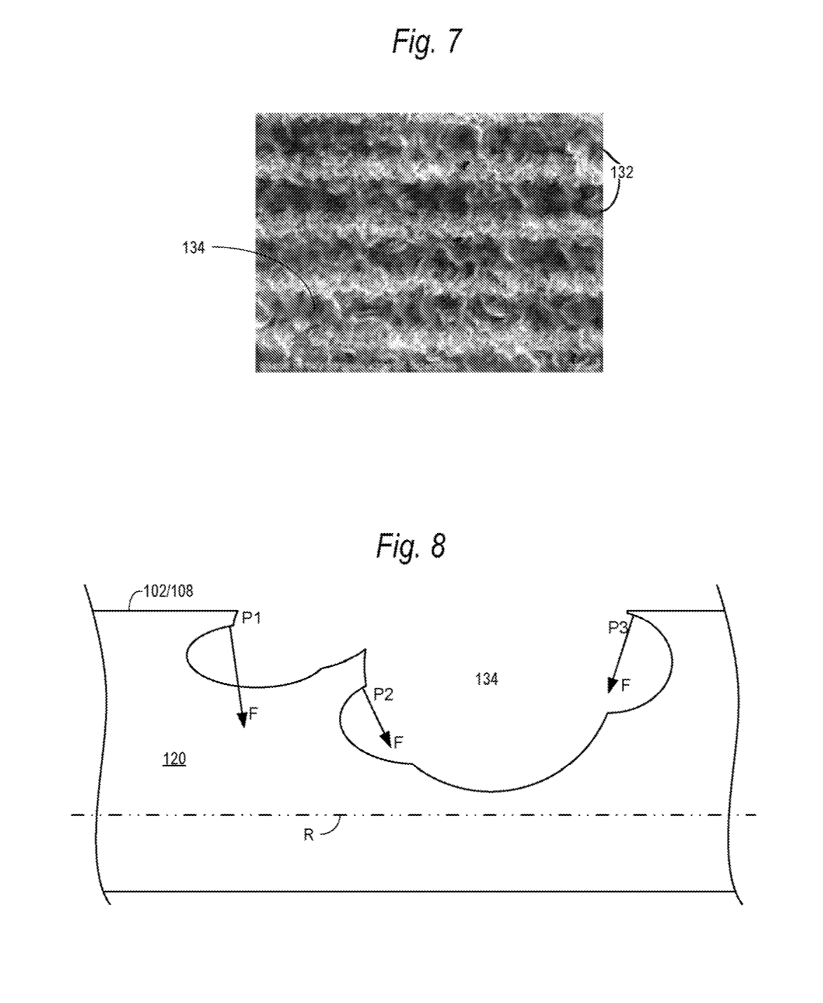

FIG. 6 is a cross-sectional view of one possible scored surface of memory device 100 transverse to the texture lines 123, and FIG. 7 is a photograph of a scored surface of memory device 100 after pre-treatment with the laser 130. The laser heats up the material on the surface 102 and/or 108 so that some of it evaporates and roughens the surface. The laser 130 may produce texture lines that are for example spaced from each other 0.08 mm or less. The spacing may be greater than 0.08 mm in further embodiments. As indicated in FIGS. 6 and 7, the lines 132 may be formed to a generally uniform depth, d, of 20 μm or less in one example. In further examples, the depth may be greater than 20 μm.

The pre-treating of the surfaces 102 and/or 108 by laser 130 may operate provide better adhesion of an ink to the surface(s) by one or more principles. FIG. 8 illustrates a first of these principals. In FIG. 8, there is shown a magnified cross-section through a line 132 shown in the photograph of FIG. 7 (the view of FIG. 8 is representative and is not an actual cross-section of any particular portion of FIG. 7). The ablation of material in the lasered-lines 132 creates a textured surface including cavities or pockmarks 134 across the surface. The cavities 134 may be microscopic in that they may be too small to be seen with the naked eye. As shown in the representative cavity 134 in FIG. 8, the cavity may have a randomly-formed, amorphous shape. This shape of cavity 134 may include jutting surfaces, undercuts and other surfaces at a wide variety of angles with respect to a reference plane R beneath the surface of mold compound 120 parallel to the surfaces 102/108 in general.

Given the randomly formed undercuts and jutting surfaces, there may exist points (e.g., P1, P2 and P3) that “overhang” and are able to exert forces F normal to their surface on any ink which fills the cavity 134, where these normal forces have a component directed toward the reference plane R. Again, the number and orientation of overhangs shown in FIG. 8 having a force component directed toward reference plane R are by way of example only. The cavities 134 created across the lasered-surface will have different configurations, some having overhangs, others possibly not having overhangs.

When an ink is applied to the surfaces 102/108 as explained hereinafter, the ink fills each cavity 134 on the textured surface. Once the ink hardens, any overhangs in a cavity 134 will exert a force on the ink in the direction of the reference plane R, consequently holding ink within the cavity 134. All such overhangs across the lasered-surface act to bind and hold the ink on the surface of the card.

Instead of or in addition to the amorphous cavities 134 described above, it is conceivable that a laser 130 may create lines 132 having relatively smooth, V-shaped sidewall cavities, such as shown for example in the representative drawing of FIG. 6. These sidewalls may not have overhangs as in FIG. 8 capable of exerting a force in the direction of the reference plane R (also shown in FIG. 6). However, according to a second adhesion principle, once ink fills the cavities of lines 132 shown in FIG. 6 and hardens, a coefficient of static friction will resist relative movement between the ink and the V-shaped sidewall cavities. The coefficient of static friction acts to bind and hold the ink in the V-shaped sidewall cavities and better adheres the ink on the surface of the card. The principle of static friction may act instead of, or in addition to, the normal forces exerted by the overhangs shown in FIG. 8.

A third adhesion principle holding the ink to the lasered-surface may be the increased surface area created by lasered-lines 132. There are adhesive forces that exist between the ink and the lasered-surface of the memory device 100. This adhesive force may result from the above-described overhangs, a coefficient of static friction, or possibly other adhesive forces (such as for example wettability discussed below). By increasing the surface area of the surfaces 102/108 with lasered lines 132, the adhesive forces exist over a larger area, thereby also increasing the adhesive forces. Thus, the increased surface area may increase the adhesiveness of the ink to the card.

A fourth adhesion principle which may hold the ink to the lasered-surface may be a capillary action by which liquid ink is drawn into cavities created on the surface 102/108 by the laser 130. In embodiments, the laser 130 may create lines 132 forming narrow enough cavities in the surface (such as shown in FIG. 6) that the liquid ink is drawn into the cavities by capillary action. As is known, capillary action occurs due to inter-molecular attractive forces between the ink and sidewalls. If the diameter of the cavities is sufficiently small, then the combination of surface tension and forces of adhesion between the liquid and cavities act to pull the liquid into the cavities, whereupon the ink may dry and adhere by any of the above-described principles.

Each of the above-identified principles occurs as a result of creating a roughened texture into the surface 102/108 of the memory device 100. It is understood that the laser 130 may create lines 132 which improve the adhesion of the ink to the lasered-surface by any one of the above-identified principles, or by a combination of these principles acting together. It is conceivable that, at least to some extent, the adhesion may be further improved by improving the wettability of the surfaces 102/108. Wettability is discussed in greater detail below with respect to the chemical pre-treatment of the surfaces 102/108.

As indicated above, graphical content may be provided on an entire surface or a portion of a surface of memory device 100. In embodiments, only those portions of a surface receiving graphical content are pre-treated by the laser 130. In further embodiments, an entire surface of panel 110, or a memory device 100 on panel 110, may be pre-treated even where only a portion of that surface is to receive graphical content. Following the scoring of a surface with laser 130, an ultrasonic cleaning process may be performed to remove burned particles from the surface. The cleaning process may be omitted in further embodiments.

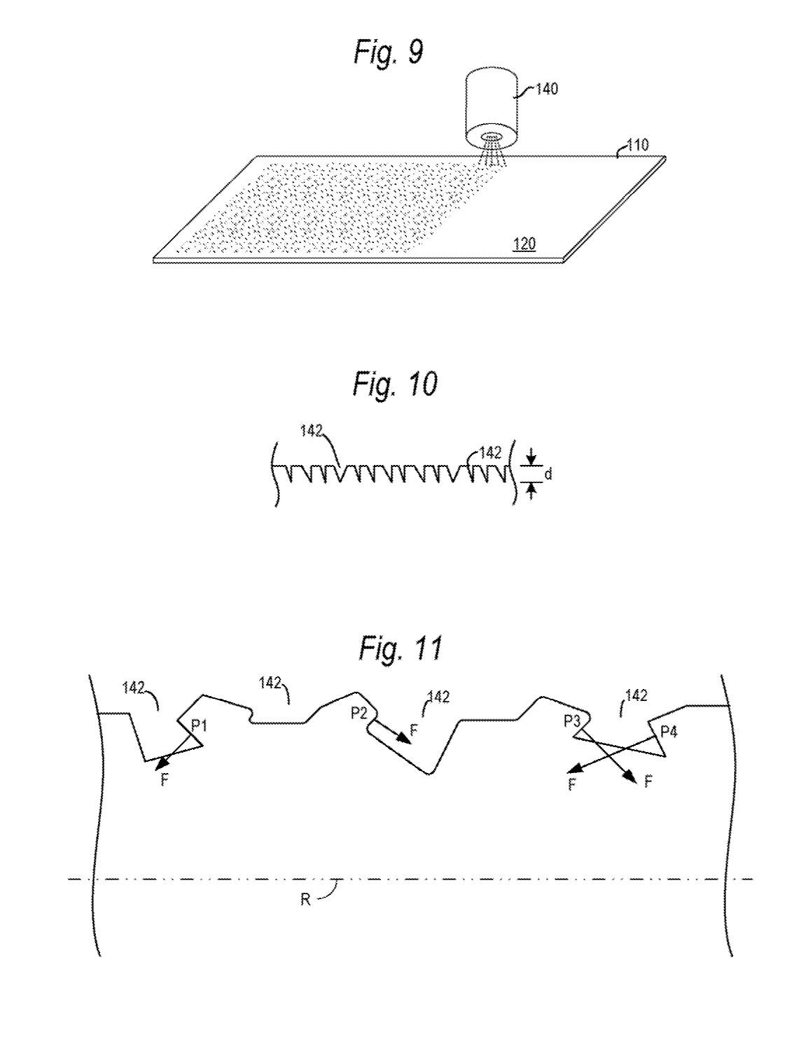

FIGS. 9-11 show a further embodiment for mechanically pre-treating surfaces of panel 110 and/or memory device 100 using a particle blaster 140. The particle blaster 140 may abrade the surface of memory device 100 by forcibly propelling a stream of abrasive material against the surface of molding compound 120 on panel 110 under high pressure. Various materials may be used as the abrasive material, including for example aluminum oxide, silicon oxide, cerium dioxide, boron oxide, carbon crystals, silicon carbide and other materials. These may be propelled against the surface as dry particles or at least some of these may be propelled in a liquid form as part of a slurry. Upon contact with the surface, the abrasive forms deformations to provide a roughened texture to the abraded surface.

One example of a system for sandblasting a surface is shown for example in U.S. Patent Publication No. 2010/0159699, entitled “Sandblast Etching For Through Semiconductor Vias,” which publication is incorporated herein by reference in its entirety. In a further embodiment, blasting may be performed with dry ice particles such as carbon dioxide crystals. In such embodiments, the deformation of the surface may occur as a result of both thermal shock (the carbon dioxide crystals being at around −80° C.) and mechanical impact of the particles on the surface. In embodiments, the abrasive particles may be approximately 50 μm, though other sizes are contemplated.

As shown in the cross-sectional view of FIG. 10, the particles may form discrete deformations 142 randomly and generally evenly spaced across a surface of panel 110. The deformations may be spaced 0.08 mm or less from each other, though this spacing may be greater than 0.08 mm in further embodiments. The deformations may for example be formed to a depth, d, of 20 μm or less in one example. In further examples, the depth may be greater than 20 μm.

The deformations 142 improve the adhesion of ink to the surface 102/108 by one or more of the principles discussed above with respect to FIGS. 5-8. The blasting may create deformations having generally V-shaped angled sidewalls as shown in the representative drawing of FIG. 10. These sidewalls may hold ink by static friction. Alternatively or additionally, the blasting may create deformations which randomly create amorphous surfaces, some of which may define overhangs as shown at points P1, P2, P3 and P4 in the representative drawing of FIG. 11. The abraded surface at points P1, P2, P3 and P4 may hold ink by exerting a force on the ink in the direction of reference plane R as described above. Both the embodiments may further improve adhesive forces by increasing the surface area over which the ink contacts the surface and/or by capillary action where a depression is defined with a narrow diameter.

In embodiments, only those portions of a surface receiving graphical content are pre-treated by the particle blaster 140. In further embodiments, an entire surface of panel 110, or a memory device 100 on panel 110, may be scored even where only a portion of that surface is to receive graphical content. FIG. 9 shows a particle plaster 140 appearing to dispense a relative narrow stream of particles that moves over the panel 110. In further embodiments, the blasted area may be larger. A particle blaster may blast an entire panel 110 or a portion of the panel 110 at one time. In such embodiments, a mask of sheet metal or other material may be placed between the panel 110 and the particle blaster 140. The mask may have openings over the areas on panel 110 to be abraded, but otherwise prevent particles from striking portions of the surface of the panel 110 that are not to be abraded.

Following the scoring of a surface with blaster 140, an ultrasonic cleaning process may be performed to remove fractured particles and grit from the surface. The cleaning process may be omitted in further embodiments.

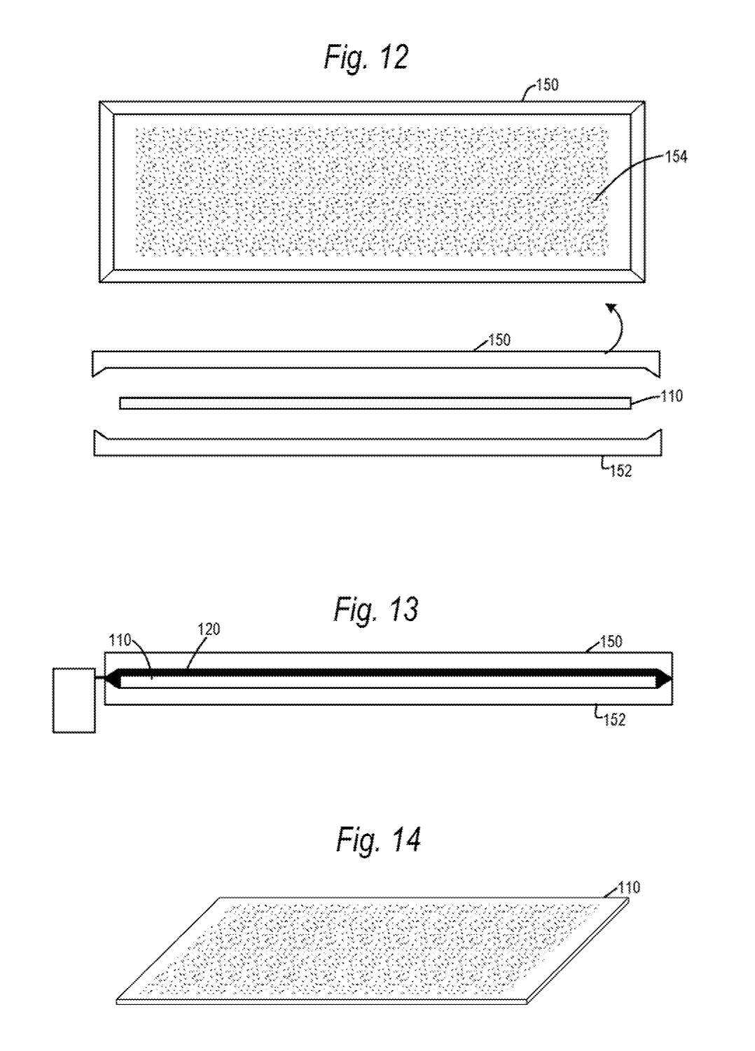

FIGS. 12-14 illustrate a further embodiment for pre-treating one or more surfaces of a memory device 100. In this embodiment, the pre-treating occurs in conjunction with the encapsulation process. FIG. 12 shows an upper mold plate 150 and a lower mold plate 152. The upper mold plate 150 is shown in FIG. 12 both in edge view, and flipped up to show an interior surface 154 of the upper mold plate 150. The interior surface 154 lies generally parallel to the panel 110 including the substrates 118 and die 112, 114 when the panel 110 is placed between the upper and lower mold plates for encapsulation in molding compound 120.

As seen, the interior surface 154 is provided with a surface roughness. The interior surface of lower mold plate 152 may additionally or alternatively be provided with a surface roughness. Moreover, only portions of upper mold plate 150 and/or lower mold plate 152 may have a surface roughness. In embodiments, this surface roughness may for example be in a range of Ra=2-10 μm, and in further embodiments, Ra=3-6 μm. It is understood that the surface roughness provided on one or both mold plates 150, 152 may be higher or lower than these ranges in further embodiments. The roughness pattern may be lines, parallel or otherwise, and/or discrete deformations.

As shown in FIG. 13, in the encapsulation process, the mold plates 150, 152 are brought together to form a cavity around the panel 110, and then molding compound 120 may be injected into the cavity by a pump or other driving mechanism 158. When the molding compound 120 is injected between the upper and lower mold plates 150, 152, the surface roughness on one or both plates 150, 152 is imprinted in the surface(s) of the molding compound 120 in the finished encapsulated panel 110, as shown in FIG. 14.

The embodiment of FIGS. 12-14 may improve the adhesion of ink to the surface 102/108 of memory device 110 by one or more of the principles discussed above with respect to FIGS. 5-11. The mold plates may create deformations having generally V-shaped angled sidewalls as shown in the representative drawing of FIG. 10 for an earlier-described embodiment. These sidewalls may improve the ability to hold ink by static friction. Alternatively or additionally, the texturing of the surface by the mold plates may further improve adhesive forces by increasing the surface area over which the ink contacts the surface and/or by capillary action where a depression in the mold compound 120 is defined with a sufficiently narrow diameter.

As described above, in addition to mechanical pre-treating, embodiments of the present system relate to chemically pre-treating the surfaces 102 and/or 108 of the memory device 100. Embodiments of chemical pre-treatment will now be described with reference to FIGS. 15-19. Instead of or in addition to roughening the texture of the surface, chemical pre-treatment may improve the wetting of the surfaces 102 and/or 108 so that the ink better adheres to the surfaces.

Wetting is the ability of a liquid to maintain contact with a solid surface, resulting from intermolecular interactions when the two are brought together. FIGS. 15 and 16 are illustrative representations of two drops of ink 122 on a surface of a memory device 100. The contact angle, θ, is the angle at which the liquid-vapor interface meets the solid-liquid interface. The contact angle is determined by the resultant between adhesive and cohesive forces at the interface. The tendency of a drop of ink to spread out over a surface of a memory device 100 increases as the contact angle θ decreases.

Thus, the contact angle provides an inverse measure of wettability. The example of FIG. 15 may be a surface of the memory device 100 before pre-treating in accordance with the present system, and FIG. 16 may be the same surface of the memory device after pre-treating in accordance with the present system. Surfaces with a high contact angle are said to have a low surface adhesion energy, where surfaces having a low contact angle are said to have a high surface adhesion energy. One mathematical relationship defines adhesion energy, ΔE, as:

ΔE=E1(1+cos(θ)), where E1 is the surface energy of the solid surface.

It can be seen that for small angles near 0°, the adhesion energy ΔE will be maximized and for large angles near 180°, the adhesion energy ΔE will be minimized. Surface adhesion energy and wettability may be improved by chemical pre-treatment of the surfaces of a memory device as explained below. It is also contemplated that mechanical texturing in one or more of the above-described embodiments improves surface adhesion energy and wettability. Examples of how mechanical abrading and other techniques may increase intermolecular surface adhesion are discussed in U.S. Patent Publication No. 2009/0181217, entitled “Ink Jet Printing On Sport Court And Other Polymer Tiles,” which application is incorporated herein by reference in its entirety.

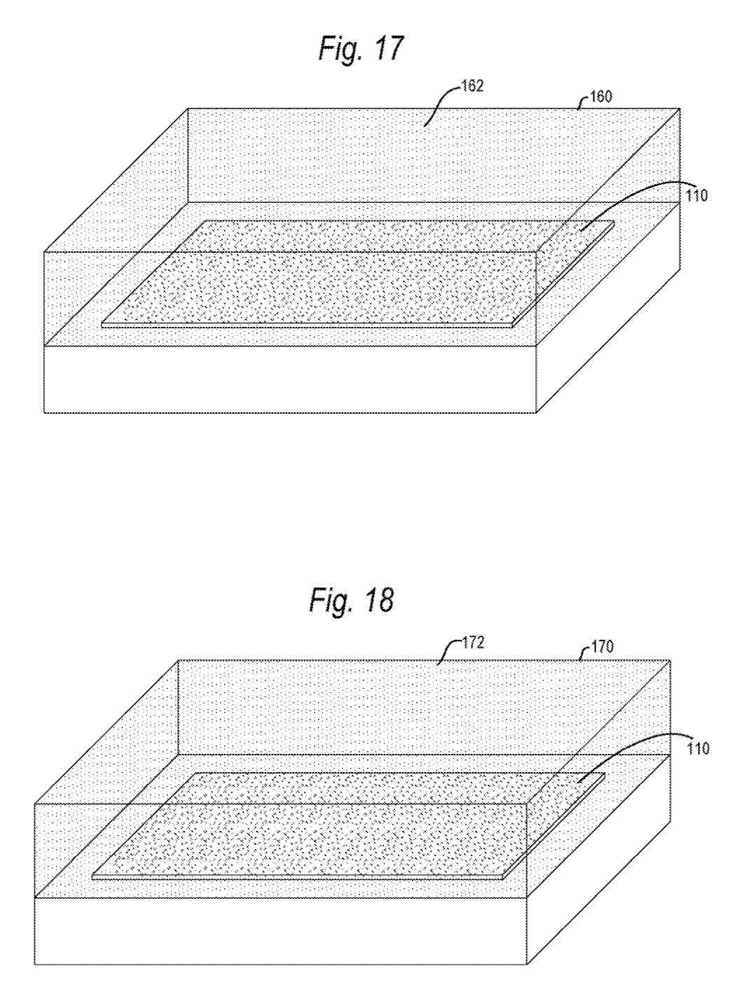

One embodiment where one or more surfaces of a panel 110 or individual memory devices 100 are chemically pre-treated is shown schematically in FIG. 17. In this embodiment, a panel 110 is placed within a chamber 160 together with a gas under a strong electric field to generate a plasma 162 within the plasma chamber 160. The plasma may for example be an ionized gas of Hydrogen, Nitrogen and/or Oxygen, though plasmas of other ionized gases may be used. Plasma processes may be used to clean surfaces of panel 110, but in this embodiment, the plasma further reacts with surface molecules of the molding compound 120 on panel 110 so that ions of the plasma gas bond with the surface of the molding compound. In embodiments, the plasma is produced by applying power and creating vacuum in the chamber 160. In one example, the power may be 150 to 250 watts and the pressure is 150-300 mTorr, and the panel 110 may be exposed to the plasma for 10 to 20 minutes. These values are by way of example and may vary above or below the given ranges in further embodiments. With these parameters, the plasma process may produce a surface roughness in a range of, for example, Ra=2-10 μm, and in further embodiments, Ra=3-6 μm. These ranges of surface roughness are provided by way of example only, and may have other values and ranges in further embodiments.

The bonding of plasma ions to the molding compound 120 roughens the surfaces to which the plasma ions bond to lower the contact angle and increase the surface energy of pre-treated surfaces for increased wettability of ink on the pre-treated surfaces. In FIG. 17, the panel 110 may be supported in such a way that both the front and back surfaces of the panel may be chemically pre-treated. If desired, some portions of the surfaces of panel 110 may be covered with an adhesive tape to prevent chemical pre-treatment according to the embodiment of FIG. 17. As noted, instead of a whole panel 110, one or more individual memory devices 100 may be placed within plasma chamber 160 and chemically pre-treated.

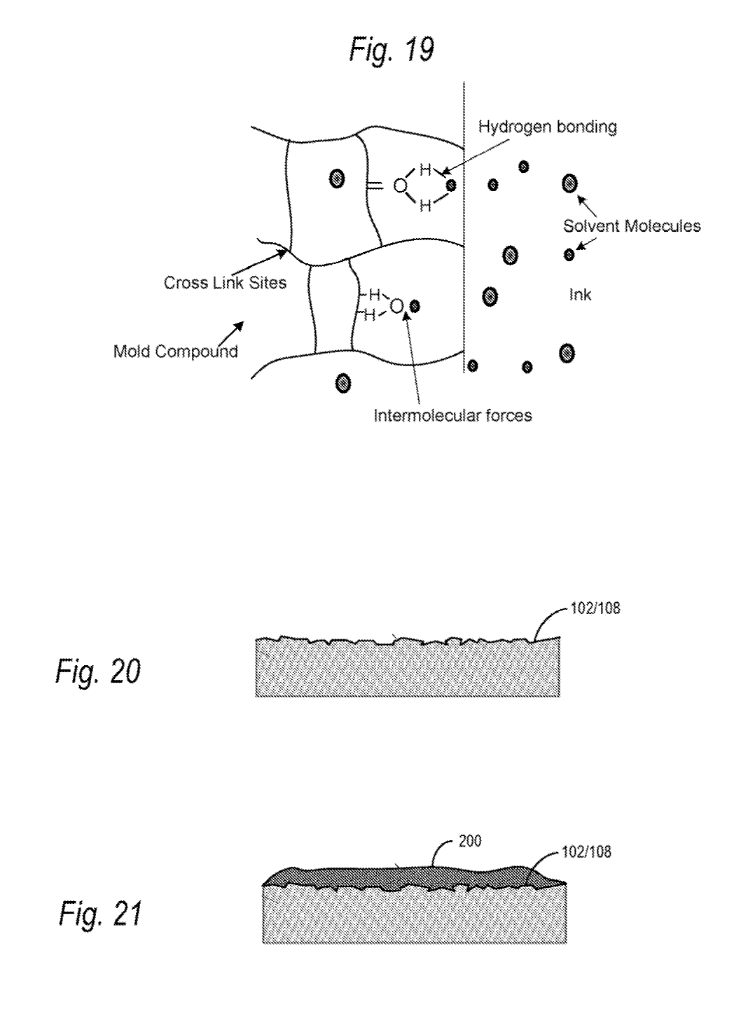

FIGS. 18 and 19 show a further embodiment for chemically pre-treating one or more surfaces of a panel 110 or individual memory devices 100. FIG. 18 shows a panel 110 within a chamber 170 including an interfacial agent 172. As indicated in the molecular view at the surface of the molding compound 120 in FIG. 19, the interfacial agent penetrates into the surface of the molding compound, breaking or weakening the C—H, H—O and/or C—O bonds in the surface molecules of the molding compound. This makes the surface of the molding compound 120 more suitable for chemical bonding with the applied ink, thus improving the wettability of the pre-treated surfaces.

Various interfacial agents 172 are known which are able to penetrate into the surface of the molding compound for breaking or weakening the molecular bonds of the molding compound 120. An example of an interfacial agent which may be used is a primer from Mimaki, Inc., having an office in Suwanee, Ga. If desired, some portions of the surfaces of panel 110 may be covered with an adhesive tape to prevent chemical pre-treatment per the embodiment of FIGS. 18 and 19. As noted, instead of a whole panel 110, one or more individual memory devices 100 may be placed within interfacial agent chamber 170 and chemically pre-treated.

FIGS. 17-19 show two examples of chemical pre-pretreatment of panel 110 or memory devices 100. It is understood that other chemical processes may be performed to pre-treat panel 110 or memory devices 100. These further chemical pre-treatment processes may either add ions, atoms or molecules onto the surface of molding compound 120, or they may break the bonds within the molding compound 120.

Once one or more surfaces 102 and/or 108 of a panel 110 or individual memory devices 100 have been pre-treated by any of the above-described embodiments, the surface is then able to receive and hold one or more layers of ink. One unique aspect of printing on memory devices 100 is that space in the thickness dimension of such devices is critical. The SD Card Association standard dictates that the thickness of a microSD card, for example, is limited to 1.00 mm. Such packages may contain four stacked memory die and a controller die, but there is a constant drive to increase memory storage capacity and the number of memory die that may be stacked in memory device 100. The wires bonds inside a memory device 100 that are used to allow signal transfer to and from the memory die may be as close as 30 microns (μm) from the top surface 102 of the memory device 100. Given these constraints, it is desirable to take up as much of the available, standard-defined thickness dimension with the memory die, bond wires and mold compound. This leaves little room for providing layers of ink on the top and/or bottom surfaces 102, 108 of the memory die 100.

However, a typical layer thickness of inkjet is 10-20 μm, and a proper color printing is at least 3-4 layers thick. This means that use of conventional ink layers would add 30-80 μm of thickness to the memory die. In order to provide this space, the height of the die, wires and/or mold compound needs to be reduced. That is not a viable option.

Therefore, the ink layers which are printed on memory device 100 are made thinner, in the range of 10-20 μm in one example. The problem with this is that thin ink layers have weaker adhesive forces than thicker layers of ink. The pre-treatment techniques described above provide sufficient adhesive forces to adhere thinner layers of ink than was previously known. The strong adhesive forces of the pre-treated surfaces is able to compensate for the relatively weak adhesive force of the ink for the surface. For example, in embodiments where the ink mechanically binds in the amorphous-shaped cavities, the ink is securely held and prevented from coming off of the surface.

Another problem that is specific to memory devices is that a lubricant such as a wax or oil is used to facilitate removal of the memory devices from the mold chamber during the encapsulation process. As discussed in the Background section, while this lubricant may be removed prior to applying the ink, the lubricant beneath the surface tends to migrate to the surface after the ink is applied, tending to further reduce the adhesive forces between the surface and the ink. However, given the strong adhesive forces of the pre-treated surfaces, again for example where the ink mechanically binds in amorphous cavities, the ink is held on the surface even where such lubricants do migrate to the surface.

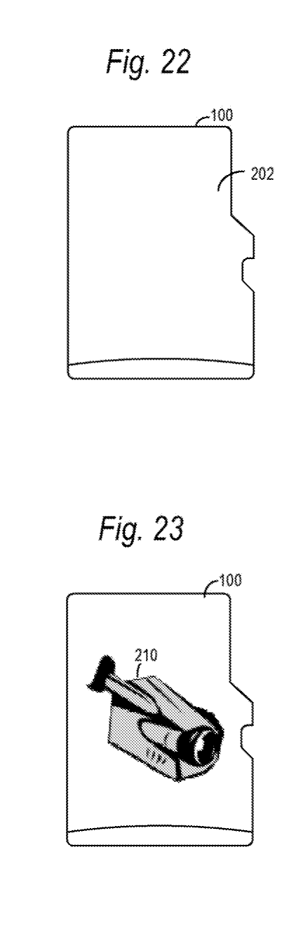

FIG. 20 shows an example of a surface 102 or 108 which is pre-treated per the present system. The ink may have a roughened texture and may have an increased adhesive ability per any of the above-described methods and principles. Thus, upon application of an ink 200 as shown in FIG. 21, the ink is held firmly to the surface. This allows rich, colorful graphical content to be printed on the pre-treated surfaces. Details relating to various methods of printing on memory devices 100 and the types of content which may be printed, are set forth in U.S. Provisional Patent Application No. 61/253,271, previously incorporated by reference. However, in embodiments, the pre-treating greatly enhances the ability to print a white primer on memory devices 100. The printable surface on memory devices, such as microSD cards, is typically a black resin; however, printing certain colors directly onto a black surface may result in a faded-looking image. Accordingly, in one embodiment, prior to printing the graphical content onto a memory device, a primer layer 202 (FIG. 22) can be printed onto the memory device 100. Primer layer 202 may be white, or shades of gray or other colors.

With or without primer layer 202, the pre-treating of the surfaces of a memory device 100 allows any of a wide variety of graphical content to be printed on the front and/or back surfaces of the memory device 100, and possibly on the edges between the front and back surfaces of the memory device. FIG. 23 shows one example of a graphical content 210 printed on pre-treated surface 102 of memory device 100. The graphical content 210 is a camera, possibly indicating that still or video images are stored on the memory device 100. The graphical content 210 may have other meanings in further embodiments. The graphical content 210 may also be provided in any color or shade in further embodiments, and may be any content which may be graphically printed.

The pre-treatment of memory devices 100 allows printing of graphical content onto the pre-treated surfaces by a wide variety of printing technologies, including for example inkjet printing and flatbed printing. Other types of printing are disclosed in the above-incorporated U.S. Provisional Patent Application No. 61/253,271.

In summary, the present technology relates to a memory device including at least one roughened surface, said surface comprising multiple cavities designed to collect and hold a layer of a fluid applied to the surface.

In another example, the present technology relates to a memory device including a surface pre-treated to increase the surface energy of the surface to facilitate better printing on the surface; and graphical content printed on the pre-treated surface.

In a further embodiment, the present technology relates to a memory device including: one or more semiconductor die; molding compound encapsulating the one or more semiconductor die, the molding compound including first and second opposed sides, the first side including electrical contacts for coupling the memory device to a host device; and a pre-treated surface on at least one of the first and second sides of the molding compound, the pre-treated surface pre-treated to increase the surface energy of the pre-treated surface to facilitate better printing on the pretreated surface.

In another example, the present technology relates to a memory device including: one or more semiconductor die; molding compound encapsulating the one or more semiconductor die, the molding compound including first and second opposed sides, the first side including electrical contacts for coupling the memory device to a host device; and a surface on at least one of the first and second sides of the molding compound, the surface having at least one of scored lines or discrete deformations for increasing a roughness of the surface to facilitate better printing on the surface.

In another embodiment, the present technology relates to a memory device including: one or more semiconductor die; molding compound encapsulating the one or more semiconductor die, the molding compound including first and second opposed sides, the first side including electrical contacts for coupling the memory device to a host device; and a surface on at least one of the first and second sides of the molding compound, the surface having particles chemically added or removed from the molding compound for increasing a roughness of the surface to facilitate better printing on the surface.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

1. A molded memory device comprising at least one roughened surface, said surface comprising multiple cavities designed to collect and hold a layer of a fluid applied to the surface.

2. The device of claim 1 wherein said surface is roughened after an encapsulation process for encapsulating the memory device in a mold compound.

3. The device of claim 2, wherein said roughening is done by particle blasting.

4. The device of claim 3, wherein said particles are dry particles.

5. The device of claim 3, wherein said particles are provided in a liquid slurry.

6. The device of claim 2 wherein said roughening is done be laser ablation.

7. The device of claim 2, further comprising a layer of fluid cured after being applied to the surface and filling said cavities.

8. The device of claim 7, wherein said fluid is a colored ink.

9. The device of claim 8, wherein said ink is applied by inkjet.

10. A memory device, comprising:
a surface pre-treated to increase the surface energy of the surface to facilitate better printing on the surface; and
graphical content printed on the pre-treated surface.

11. The memory device of claim 10, the memory device including molding compound for encapsulating internal components, the pre-treated surface being a surface of the molding compound.

12. The memory device of claim 11, wherein the memory device includes first and second sides, the first side including electrical contacts, the pre-treated surface being on one of the first and second surfaces.

13. The memory device of claim 12, wherein the pre-treated surface is a first pre-treated surface, the memory device further including a second surface on the first or second side not having the first pre-treated surface, the second pre-treated surface increasing the surface energy of the second surface to facilitate better printing on the second surface.

14. The memory device of claim 10, wherein the pre-treated surface includes a surface roughness defined by a plurality of scored lines.

15. The memory device of claim 14, wherein the plurality of scored lines are parallel to each other.

16. The memory device of claim 10, wherein the pre-treated surface includes a surface roughness defined by a plurality of deformations.

17. The memory device of claim 16, wherein the plurality of deformations resulted from particle blasting.

18. The memory device of claim 10, the pre-treated surface formed in a molding compound on the memory device, the pre-treated surface has a surface roughness matching a mold plate that applied the molding compound to the memory device.

19. The memory device of claim 10, wherein the pre-treated surface includes particles from a plasma adhered to the surface to provide the surface with a surface roughness.

20. The memory device of claim 19, wherein particles are from an ion plasma of Hydrogen, Nitrogen or Oxygen.

21. The memory device of claim 10, wherein the pre-treated surface has molecular bonds which are weakened or broken with an interfacial agent.

22. The memory device of claim 10, wherein the memory device is a MicroSD card.

23. A memory device, comprising:
one or more semiconductor die;
molding compound encapsulating the one or more semiconductor die, the molding compound including first and second opposed sides, the first side including electrical contacts for coupling the memory device to a host device; and
a pre-treated surface on at least one of the first and second sides of the molding compound, the pre-treated surface pre-treated to increase the surface energy of the pre-treated surface to facilitate better printing on the pretreated surface.

24. The memory device of claim 23, wherein the pre-treated surface takes up the entire second side of the memory device.

25. The memory device of claim 23, wherein the pre-treated surface takes up the entire second side of the memory device except of a raised area forming a finger grip.

26. The memory device of claim 23, wherein the pre-treated surface takes up the entire first side of the memory device except for an area occupied by the electrical contacts.

27. The memory device of claim 23, wherein the pre-treated surface is pretreated together with other memory devices before singulation.

28. The memory device of claim 23, wherein the pre-treated surface is pretreated after it is singulated from other memory devices.

29. A memory device, comprising:
one or more semiconductor die;
molding compound encapsulating the one or more semiconductor die, the molding compound including first and second opposed sides, the first side including electrical contacts for coupling the memory device to a host device; and
a surface on at least one of the first and second sides of the molding compound, the surface having at least one of scored lines or discrete deformations for increasing a roughness of the surface to facilitate better printing on the surface.

30. The memory device of claim 29, wherein the surface includes scored lines which are parallel to each other across the surface.

31. The memory device of claim 30, wherein the scored lines are spaced from each other 0.08 mm or less.

32. The memory device of claim 31, wherein the scored lines have a depth of 20 μm or less.

33. The memory device of claim 29, wherein the surface includes discrete deformations randomly and evenly distributed across the surface.

34. A memory device, comprising:
one or more semiconductor die;
molding compound encapsulating the one or more semiconductor die, the molding compound including first and second opposed sides, the first side including electrical contacts for coupling the memory device to a host device; and
a surface on at least one of the first and second sides of the molding compound, the surface having particles chemically added or removed from the molding compound for increasing a roughness of the surface to facilitate better printing on the surface.

35. The memory device of claim 34, wherein particles adhere to the surface of the molding compound are from a plasma.

36. The memory device of claim 34, wherein particles are removed from the surface by an interfacial agents that weakens or breaks molecular bonds in a surface of the molding compound.
